(19) United States
(12) Patent Application Publication
(10) Pub. No.: US 2026/0105588 A1
(43) Pub. Date: Apr. 16, 2026

(54) FITTING ROUNDED QUADRILATERAL SHAPES IN SEM IMAGING

(71) Applicant: Applied Materials Israel Ltd., Rehovot (IL)

(72) Inventors: Ahram Lee, Suwon-si (KR); Dror ALUMOT, Tel-Aviv (IL); Tal BEN-SHLOMO, Givatayim (IL); Tal FRANK, Tel-Aviv (IL); Ji Ho KIM, Seongnam-si (KR)

(21) Appl. No.: 18/912,493

(22) Filed: Oct. 10, 2024

(51) Int. Cl. G06T 7/00; G06T 7/33; G06T 7/60; H01L 21/67

(52) U.S. Cl. CPC G06T 7/001; G06T 7/337; G06T 7/60; H10P 72/0616; G06T 2207/10061; G06T 2207/30148

(57) ABSTRACT

A system for rounded quadrilateral shape fitting that incudes obtaining a contour associated with an approximated quadrilateral shape with rounded corners of a representative pattern in a semiconductor wafer and smoothing the contour. Then, obtaining geometrical parameters associated with a contour of a reference shape and performing iteratively until a similarity criterion is met: a) converting the updated geometrical parameters generated in the current iteration to a corresponding contour of a reference shape, (b) fitting the corresponding contour of the reference shape to the smoothed contour and c) testing whether the fitted contour of the reference shape and the smoothed contour meet a similarity criterion, and, if not met, applying a numerical optimization to the updated geometrical parameters and moving to the next iteration.

### TECHNICAL FIELD

The presently disclosed subject matter relates, in general, to the field of fitting rounded quadrilateral shapes in (Scanning Electron Microscope (SEM)) imaging.

### BACKGROUND

Current demands for high density and performance, associated with ultra large-scale integration of fabricated devices, require submicron features, increased transistor and circuit speeds, and improved reliability. As semiconductor processes progress, pattern dimensions, such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Examination can be provided by using non-destructive examination tools during or after manufacture of the wafer to be examined. Examination generally involves generating certain output (e.g., images, signals, etc.) for a wafer by directing light or electrons to the wafer, and detecting the light or electrons from the wafer. A variety of non-destructive examination tools includes, by way of non-limiting example, scanning electron microscopes, atomic force microscopes, optical inspection tools, etc.

Examination processes can include a plurality of examination steps. The manufacturing process of a semiconductor device can include various procedures such as etching, depositing, planarization, growth such as epitaxial growth, implantation, etc. The examination steps can be performed a multiplicity of times, for example after certain process procedures, and/or after the manufacturing of certain layers, or the like. Additionally, or alternatively, each examination step can be repeated multiple times, for example for different wafer locations, or for the same wafer locations with different examination settings.

Examination processes are used at various steps during semiconductor fabrication for performing e.g. defect related operations. Effectiveness of examination can be improved by automatization of certain process(es) such as, for example, defect detection, Automatic Defect Classification (ADC), Automatic Defect Review (ADR), image segmentation and/or other operations, etc. Automated examination systems ensure that the parts manufactured meet the quality standards expected and provide useful information on adjustments that may be needed to the manufacturing tools, equipment, and/or compositions, depending on the type of errors identified, so as to promote higher yield.

### SUMMARY

In accordance with an aspect of the invention, there is provided a system for rounded quadrilateral shape fitting comprising a processing and memory circuitry (PMC) configured to:
obtain a contour associated with an approximated quadrilateral shape with rounded corners of a representative pattern in a semiconductor wafer and smoothing the contour;
obtain geometrical parameters associated with a contour of a reference shape;
perform iteratively until a similarity criterion is met:
   a) convert the updated geometrical parameters generated in the current iteration to a corresponding contour of a reference shape;
   (b) fit the corresponding contour of the reference shape to the smoothed contour;
   (c) test whether the fitted contour of the reference shape and the smoothed contour meet a similarity criterion, and if the similarity criterion is not met, apply a numerical optimization to at least one of the updated geometrical parameters from the current iteration to generate a new set of updated geometrical parameters for use in a subsequent iteration,
thereby, if the similarity criterion is met, enabling detection of defects in patterns of a semiconductor wafer utilizing at least updated geometrical parameters generated in one of the iterations, wherein the patterns resemble a quadrilateral shape with rounded corners.

In addition to the above features, the system according to this aspect of the presently disclosed subject matter can comprise one or more of features (i) to (xi) listed below, in any desired combination or permutation which is technically possible:
(i) wherein the reference shape is a quadrilateral shape with rounded corners.
(ii) wherein the PMC is configured to fit the reference shape to the smoothed contour in at least two fitting stages, wherein, in each stage, a distinct number of the initial parameters are updated to thereby improve computational complexity compared to the computational complexity, had all the initial parameters been updated in a single fitting stage.
(iii) wherein the PMC is configured to utilize different fitting techniques for at least two of the stages.
(iv) wherein said PMC is configured to fit the reference quadrilateral shape with rounded corners to the smoothed contour in two fitting stages, wherein, in the first stage, the fitting includes an IoU fitting technique, and the center (x,y), width, height, angle, corner radius updated parameters of the fitted quadrilateral shape are determined, and in the second stage the fitting includes a Boundary IoU technique, and the four corner radii updated parameters of the fitted quadrilateral shape are determined.
(v) wherein the PMC is configured to fit the reference quadrilateral shape with rounded corners to the smoothed contour in two fitting stages, wherein, in the first stage, the fitting includes an IoU fitting technique, and the four vertex points (x,y) updated parameters of the fitted shape with rounded corners are determined, and in the second stage the fitting includes a Boundary IoU technique, and the four corner radii updated parameters of the fitted quadrilateral shape are determined.
(vi) wherein the PMC is configured to fit the reference shape with rounded corners to the smoothed contour in n fitting stages, wherein n is the number of updated geometrical parameters.
(vii) wherein the PMC is configured to obtain the contour associated with an approximated quadrilateral shape with rounded corners of a representative pattern in a semiconductor wafer, including:
   determine a finite number of contour points that are distributed across every side and every vertex of the approximated quadrilateral shape;
   extrapolate the contour of the model based on said determined plurality of contour points.
(viii) wherein the PMC is configured to determine the finite number of contour points, including:
   utilize an auxiliary shape that substantially overlaps the approximated quadrilateral shape with rounded corners;
   determine a finite number of strips that correspond to the finite number of contour points, respectively, wherein each of the strips traverses the contour of the quadrilateral shape, by starting outside the shape and ending inside the shape, such that the point of traversal constitutes the corresponding contour point.
(ix) wherein the auxiliary shape is fed as an input.
(x) wherein the (PMC) is configured to smooth the contour utilizing an Elliptical Fourier Descriptor (EFD) technique.
(xi) wherein the initial parameters include center (x,y), width, height, angle, and a corner radius.

In accordance with other aspects of the presently disclosed subject matter, there is provided a method for rounded quadrilateral shape fitting, comprising, by a processing and memory circuitry (PMC):
obtaining a contour associated with an approximated quadrilateral shape with rounded corners of a representative pattern in a semiconductor wafer and smoothing the contour;
obtaining geometrical parameters associated with a contour of a reference shape [not necessarily with rounded corners]
performing iteratively until a similarity criterion is met:
   a) converting the updated geometrical parameters generated in the current iteration to a corresponding contour of a reference shape;
   (b) fit the corresponding contour of the reference shape to the smoothed contour;
   (c) test whether the fitted contour of the reference shape and the smoothed contour meet a similarity criterion, and if the similarity criterion is not met, apply a numerical optimization to at least one of the updated geometrical parameters from the current iteration to generate a new set of updated geometrical parameters for use in a subsequent iteration,
thereby, if the similarity criterion is met, enabling detection of defects in patterns of a semiconductor wafer utilizing at least updated geometrical parameters generated in one of the iterations, wherein the patterns resemble a quadrilateral shape with rounded corners.

This aspect of the disclosed subject matter can comprise one or more of features (i) to (xi) listed above with respect to the system, mutatis mutandis, in any desired combination or permutation which is technically possible.

In accordance with other aspects of the presently disclosed subject matter, there is provided a non-transitory computer readable storage medium tangibly embodying a program of instructions that, when executed by a computer, cause the computer to perform a method for rounded quadrilateral shape fitting, comprising, by a processing and memory circuitry (PMC):
obtaining a contour associated with an approximated quadrilateral shape with rounded corners of a representative pattern in a semiconductor wafer and smoothing the contour;
obtaining geometrical parameters associated with a contour of a reference shape;
performing iteratively until a similarity criterion is met:
   a) converting the updated geometrical parameters generated in the current iteration to a corresponding contour of a reference shape;
   (b) fit the corresponding contour of the reference shape to the smoothed contour;
   (c) test whether the fitted contour of the reference shape and the smoothed contour meet a similarity criterion, and if the similarity criterion is not met, apply a numerical optimization to at least one of the updated geometrical parameters from the current iteration to generate a new set of updated geometrical parameters for use in a subsequent iteration,
      thereby, if the similarity criterion is met, enabling detection of defects in patterns of a semiconductor wafer utilizing at least updated geometrical parameters generated in one of the iterations, wherein the patterns resemble a quadrilateral shape with rounded corners, and wherein the reference shape is a quadrilateral shape with rounded corners.

This aspect of the disclosed subject matter can comprise one or more of features (i) to (xi) listed above with respect to the system, mutatis mutandis, in any desired combination or permutation which is technically possible.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1A illustrates, schematically, exemplary rectangles with round corners like shapes of patterns that form part of a wafer;

FIG. 1B illustrates, schematically, an exemplary etching problem as indicated by measured roundness extent of patterns on a wafer;

FIG. 1C illustrates graphically an exemplary result of a fitting technique according to the prior art and in accordance with certain embodiments of the invention;

FIG. 2 illustrates a generalized block diagram of a system for fitting rounded quadrilateral shapes in SEM imaging, in accordance with certain embodiments of the presently disclosed subject matter;

FIG. 3 illustrates a generalized block diagram of a sequence of operations in a system, in accordance with certain embodiments of the presently disclosed subject matter;

FIG. 4A illustrates schematically how to generate a contour, in accordance with certain embodiments of the presently disclosed subject matter;

FIG. 4B illustrates schematically a one-dimensional profile that serves for determining the contour, in accordance with certain embodiments of the presently disclosed subject matter;

FIG. 5 illustrates schematically, smoothing techniques, in accordance with certain embodiments of the presently disclosed subject matter;

FIG. 6A illustrates schematically an initial stage in a fitting sequence of operations, in accordance with certain embodiments of the presently disclosed subject matter;

FIG. 6B illustrates an exemplary numerical optimization and fitting sequence of operations, in accordance with certain embodiments of the presently disclosed subject matter;

FIG. 7 illustrates schematically a fitting sequence of operations, in accordance with certain embodiments of the presently disclosed subject matter;

FIG. 8 illustrates schematically an exemplary two-stage fitting sequence of operations, in accordance with certain embodiments of the presently disclosed subject matter; and

FIG. 9 illustrates schematically a sequence of operations for extracting exemplary updated geometrical parameters associated with the fitted shape, in accordance with certain embodiments of the presently disclosed subject matter.

### DETAILED DESCRIPTION OF EMBODIMENTS

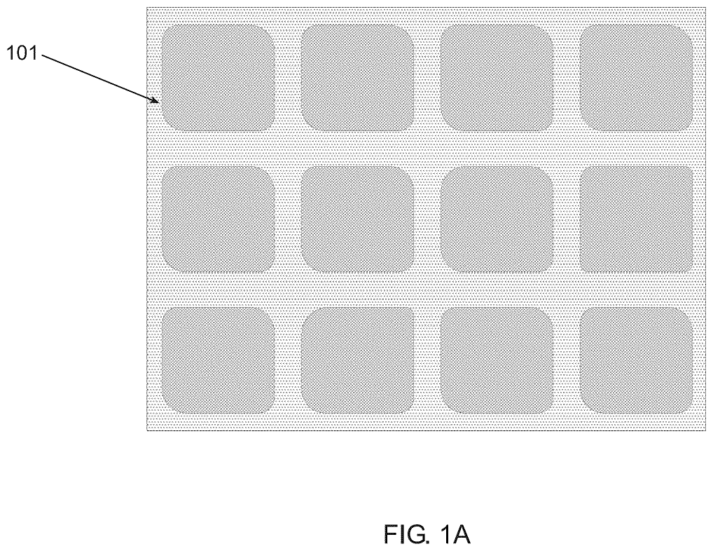

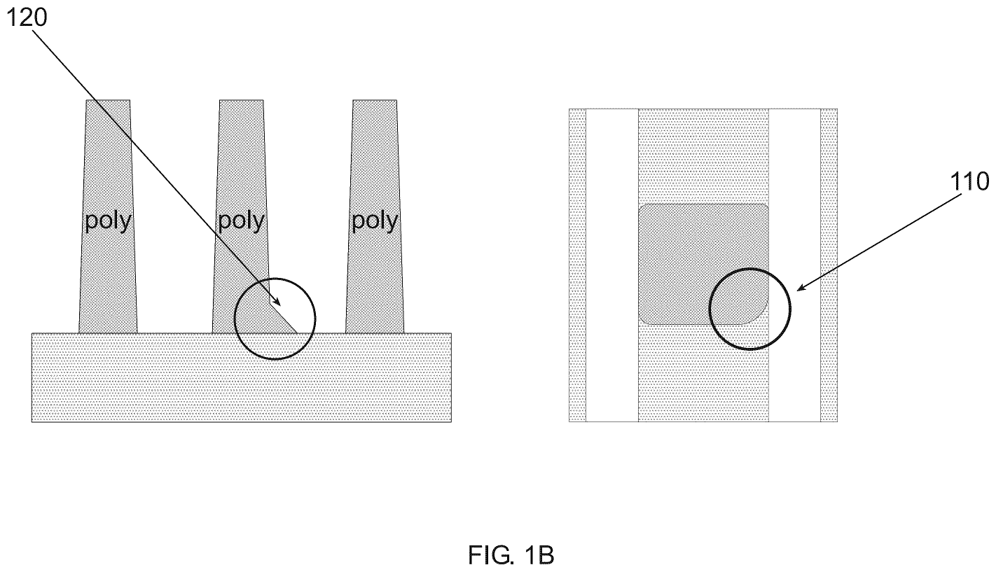

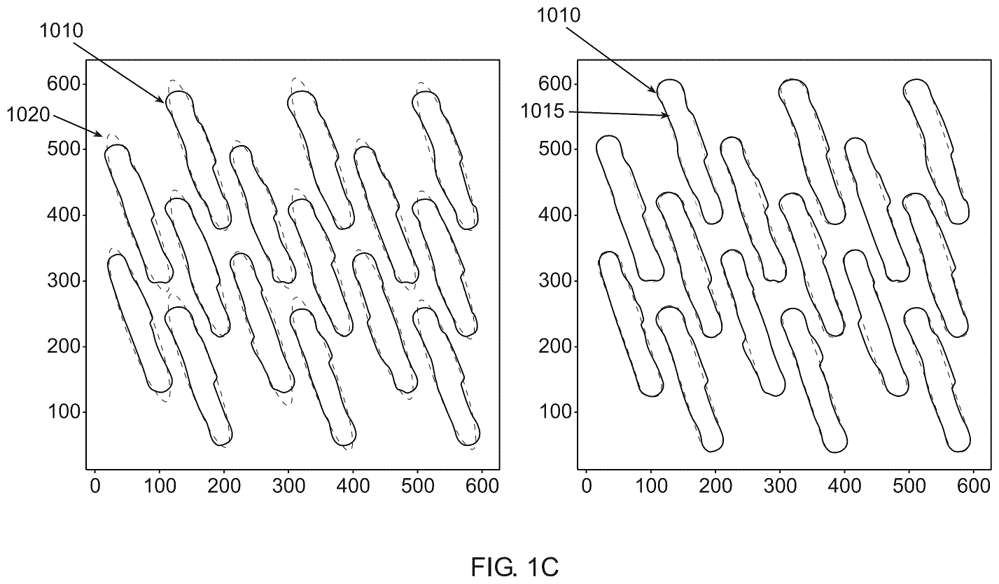

The process of making electronic chips involves etching, namely removing material from the wafer's surface to create very tiny and precise patterns on a silicon wafer. These patterns, which are typically of an approximated quadrilateral (e.g. rectangle) with rounded corners shape (see, e.g. exemplary pattern 101 of FIG. 1A as shown in images of a wafer obtained by a known per se SEM tool). These patterns need to be exact in every detail for the chip to work properly. There is a need to measure, with high precision, parameters of the specified patterns, such as radii of the corners of the quadrilateral shape, its center, width, height, etc. These parameters may be indicative of defects in the manufactured wafers. As is well known, defects in a semiconductor wafer can occur at any stage of the manufacturing process, from the initial growth of the silicon wafer to the final packaging stage. These defects can range in size from microscopic imperfections to large cracks or chips.

For instance, the measurement roundness level of the pattern 110 (see FIG. 1B) may indicate an etching problem such as unetched poly residue 120. A more rounded corner, particularly if it deviates significantly from the intended design (e.g., larger radii than planned), can be symptomatic of several potential problems in the etching process.

Accurate measurement of pattern parameters, including the roundness of corners, can contribute significantly to better determination of overlay misalignment (OVL) in semiconductor manufacturing processes. Overlay misalignment refers to the degree to which layers of patterns on a semiconductor wafer are out of alignment with each other, which is critical for ensuring the functionality and performance of the integrated circuits. They may also serve for determining known per se Measurement-Based-Inspection (MBI), Distance to shape (CD), and/or possibly other parameters.

As is well known, accurate measurements of OVL, CD, MBI, etc. are not just metrics of process performance, but are useful means for defect detection, process control, yield management, etc. in semiconductor manufacturing. They enable a deeper understanding of the manufacturing process, leading to more effective interventions and optimizations.

Bearing this in mind, intuitively, in accordance with certain embodiments of the invention there is provided a system for rounded quadrilateral shape fitting comprising a processing and memory circuitry (PMC) configured to:
obtain a contour associated with an approximated quadrilateral shape with rounded corners of a representative pattern in a semiconductor wafer and smoothing the contour;
obtain geometrical parameters (such as width height etc.) associated with a contour of a reference shape (for instance, a quadrilateral shape, possibly with rounded corners);
   perform iteratively until a similarity criterion is met:
   a) convert the updated geometrical parameters generated in the current iteration to a corresponding contour of a reference shape;
   (b) fit the corresponding contour of the reference shape to the smoothed contour;
   (c) calculate a similarity criterion between the fitted contour of the reference shape and the smoothed contour, and if said similarity criterion is not met, apply a numerical optimization to at least one of said updated geometrical parameters from the current iteration to generate a new set of updated geometrical parameters for use in a subsequent iteration,
   thereby, if said similarity criterion is met, enabling detection of defects in patterns of a semiconductor wafer utilizing at least updated geometrical parameters generated in one of said iterations (preferably in the last iteration), wherein the patterns resemble a quadrilateral shape with rounded corners.

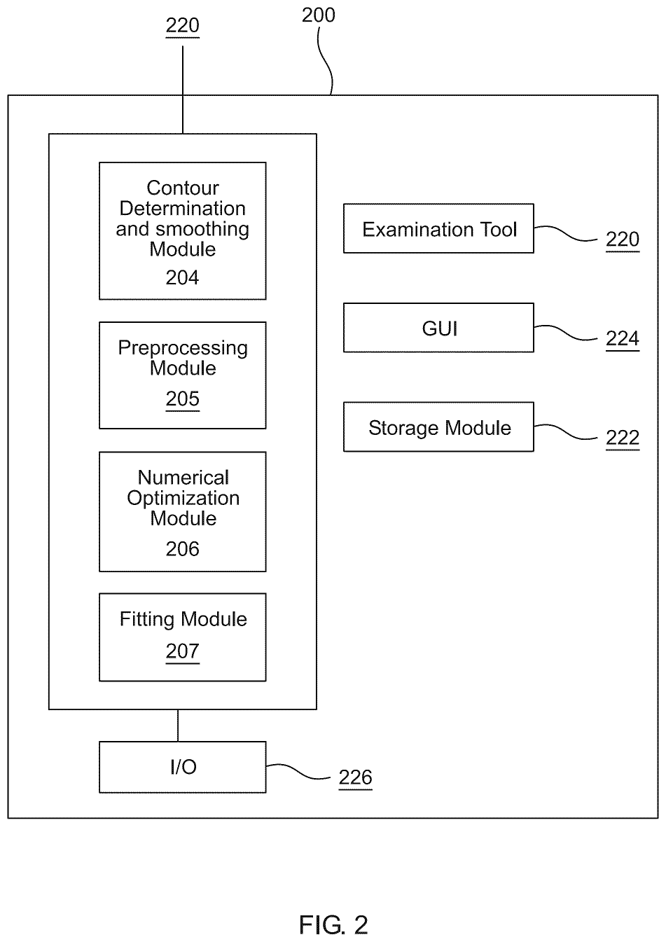

Bearing this in mind, attention is drawn to FIG. 2 illustrating a generalized block diagram of a system for fitting a rounded quadrilateral shape in accordance with certain embodiments of the presently disclosed subject matter.

The system 200 illustrated in FIG. 2 can be used for rounded quadrilateral shape fitting enabling detection of defects in patterns of a semiconductor wafer (e.g. by improving precision of OVL, CD, and MBI calculation), all as will be explained in greater detail below.

Without limiting the scope of the disclosure, it should also be noted that the examination tools 220 can be implemented as inspection machines of various types, such as optical inspection machines, electron beam inspection machines (e.g., Scanning Electron Microscope (SEM) [e.g., defect review,], Atomic Force Microscopy (AFM), or Transmission Electron Microscope (TEM), etc.), and so on. In some cases, the same examination tool can provide low-resolution image data and high-resolution image data. The resulting image data (low-resolution image data and/or high-resolution image data) can be transmitted, directly or via one or more intermediate systems, to system 201. The present disclosure is not limited to any specific type of examination tools and/or the resolution of image data resulting from the examination tools.

In some embodiments, at least one of the examination tools 220 can be configured to capture images and perform operations on the captured images.

According to certain embodiments, the examination tool can be an electron beam tool, such as, e.g., a scanning electron microscope (SEM). A SEM is a type of electron microscope that produces images of a wafer by scanning the wafer with a focused beam of electrons. The electrons interact with atoms in the wafer, producing various signals that contain information on the surface topography and/or composition of the wafer.

According to certain embodiments of the presently disclosed subject matter, the examination system 200 comprises a computer-based system 201 operatively connected to the examination tools 220 including but not limited to on-line operation, where images obtained by the examination tool are processed by the various modules of Processing Memory Circuitry (PMC) 202, or, in accordance with other non-limiting embodiments, images obtained by examination tool 220 are received through I/O module 226, and stored in storage module 222 for later off-line processing by PMC 202, all as will be explained in greater detail below.

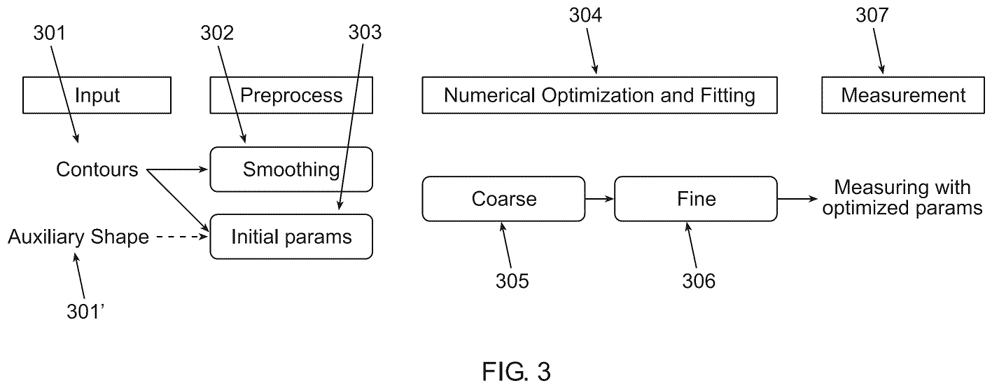

Specifically, system 201 includes a processor and memory circuitry (PMC) 202 operatively connected to a hardware-based I/O interface 226. The PMC 202 is configured to provide processing necessary for operating the system, as further detailed with reference to FIG. 3 and onwards, and comprises one or more processors (not shown separately) operatively connected to a memory (not shown separately). The processor(s) of PMC 202 can be configured to execute several functional modules in accordance with computer-readable instructions implemented on a non-transitory computer-readable memory comprised in the PMC. Such functional modules are referred to hereinafter as comprised in the PMC.

Functional modules comprised in the PMC 102 of system 101 can include, e.g., contour determination and smoothing module 204, a preprocessing module 205, numerical optimization module 206, and fitting module 207.

The PMC 202 can be configured to obtain, via the I/O interface 226 and from the examination tool 220, data indicative of images that include patterns on semiconductor wafers, which are typically of quadrilateral-like with rounded corners shape, all as will be explained in greater detail below.

Operation of systems 200, 201, 202, and the PMC(s) thereof, as well as the functional modules therein, will be further detailed with reference to FIG. 3 and onwards.

In some cases, additionally to system 201, the examination system 100 can comprise one or more examination modules, such as, e.g., defect detection module and/or Automatic Defect Review Module (ADR), and/or Automatic Defect Classification Module (ADC,) and/or other examination modules which are usable for examination of a wafer. The one or more examination modules can be implemented as stand-alone computers, or their functionalities (or at least part thereof) can be integrated with the examination tool 220. In some cases, the output of system 201 such as, e.g., the specified images, can be provided to the one or more examination modules for further processing.

According to certain embodiments, system 201 can comprise a storage unit 222. The storage module 222 can be configured to store any data necessary for operating system 201, e.g., data related to input and output of system 201, as well as intermediate processing results generated by system 201. By way of example, the storage module 222 can be configured to store images of the wafer and/or derivatives thereof produced by the examination tool 220. Accordingly, the images can be retrieved from storage module 222 and provided to the PMC 202 for further processing. The output of system 201 can be sent to storage module 222 to be stored. The specified storage unit may further store, by way of example, desired probability function, training criterion, training loss value L etc., all as will be explained in greater detail below.

In some embodiments, system 200 can optionally comprise a computer-based Graphical User Interface (GUI) 224 which is configured to enable user-specified inputs related to system 201. For instance, the user can be presented with a visual representation of the wafer (for example, by a display forming part of GUI 124), including image data of the wafer. The user may be provided, through the GUI, with options of defining certain operation parameters. The user can also annotate the reference image via the GUI. The user may also view the operation results on the GUI.

In some cases, system 201 can be further configured to send, via I/O interface 226, the output data to one or more of the examination tools, for further processing. In some cases, system 201 can be further configured to send certain output data to the storage module 222, and/or external systems (e.g., Yield Management System (YMS) of a fabrication plant (FAB)).

Those versed in the art will readily appreciate that the teachings of the presently disclosed subject matter are not bound by the system illustrated in FIG. 2, and in particular not by any of the specified modules 204, 205, 206, and 207, and/or by the operations performed thereby, as described below with reference to FIG. 3 and onwards. Equivalent and/or modified functionality can be consolidated or divided in another manner, and can be implemented in any appropriate combination of software with firmware and/or hardware.

It is noted that the system illustrated in FIG. 2 can be implemented in a distributed computing environment, in which the aforementioned components and functional modules shown in FIG. 2 can be distributed over several local and/or remote devices, and can be linked through a communication network. For instance, the examination tool 220 and the system 201 can be located at the same entity (in some cases hosted by the same device), or distributed over different entities.

It is further noted that in some embodiments at least some of examination tools 220, storage module 222, and/or GUI 224 can be external to the examination system 200 and operate in data communication with systems 200 and 201 via I/O interface 226. System 201 can be implemented as stand-alone computer(s) to be used in conjunction with the examination tools, and/or with the additional examination modules as described above. Alternatively, the respective functions of the system 201 can, at least partly, be integrated with one or more examination tools 220, thereby facilitating and enhancing the functionalities of the examination tools 220 in examination-related processes.

While not necessarily so, the process of operation of systems 201 and 200 can correspond to some or all of the stages of the methods described with respect to FIG. 3 and onwards. Likewise, the methods described with respect to FIG. 3 and onwards, and their possible implementations, can be implemented by systems 201 and 200, possibly utilizing modules 204, 205, 206, and 207. It is therefore noted that embodiments discussed with respect to FIG. 3 and onwards can also be implemented, mutatis mutandis, as various embodiments of the systems 201 and 200, and vice versa.

Attention is now drawn to FIG. 3, illustrating a generalized block diagram of a sequence of operations in a system, in accordance with certain embodiments of the presently disclosed subject matter.

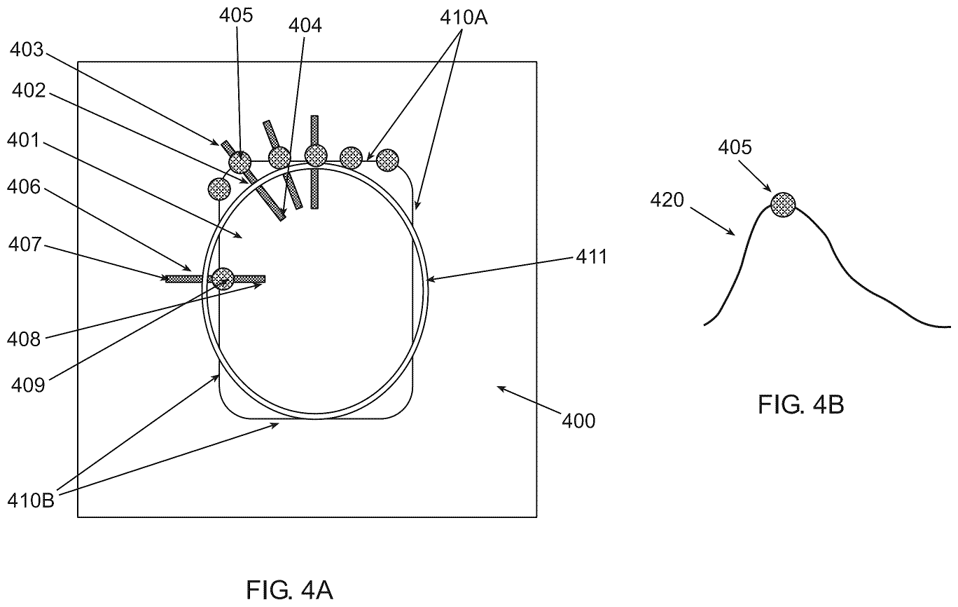

The specified sequence of operations may be implemented e.g. in modules 204 through 207 running on PMC 202 of FIG. 2. At the first stage 301, a contour associated with an approximated quadrilateral shape with rounded corners of a representative pattern in a semiconductor wafer may be obtained. The latter may be fed from external source, e.g., from storage module 222, or, in accordance with another example, may be calculated, e.g., in module 204. The calculation of the contour in accordance with various embodiments of the invention will be described in greater detail with reference to FIGS. 4A and 4B below. Note that for generation of the contour, there is a need to utilize an approximated quadrilateral shape with rounded corners of a representative pattern in a semiconductor wafer, all as will be explained in greater detail with reference to FIG. 4 below.

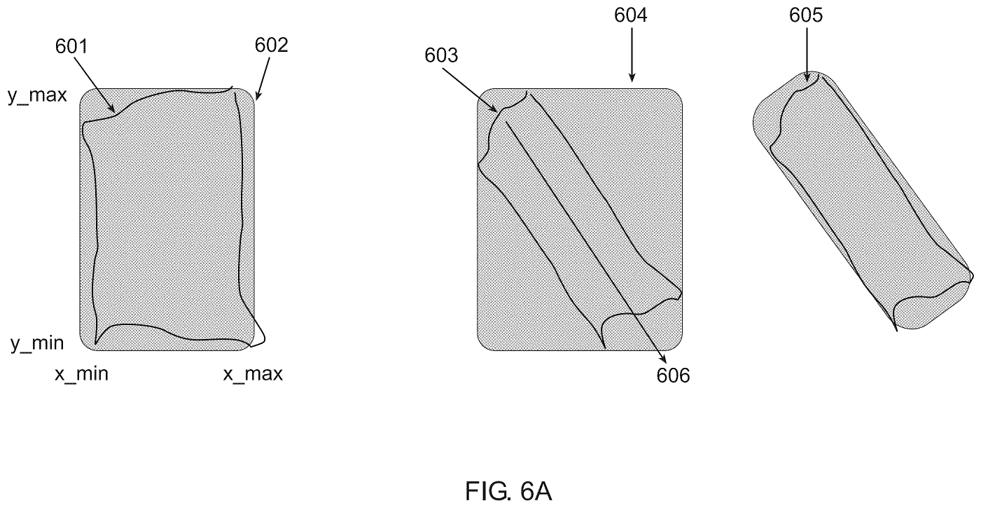

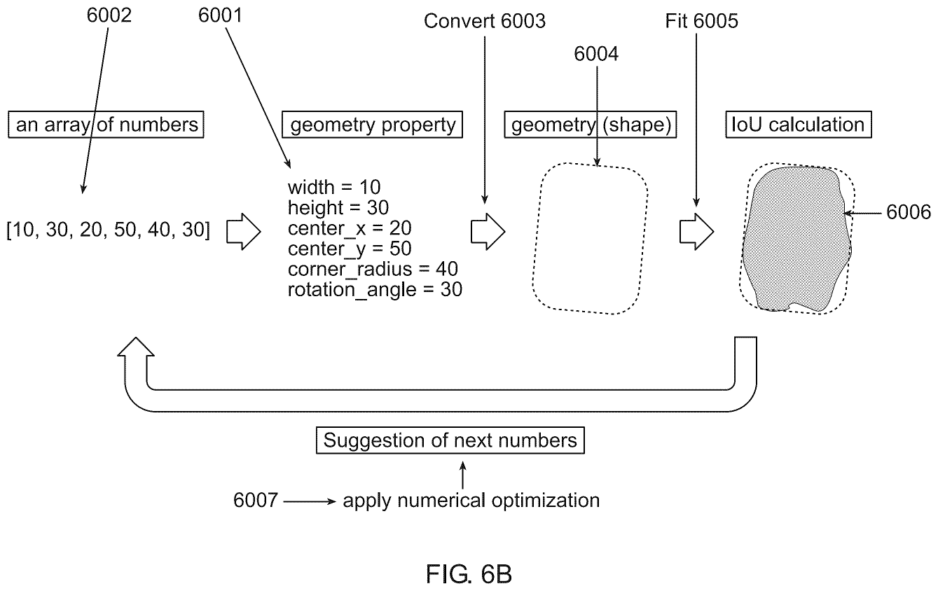

Having obtained the contour, there follows a smoothing phase 302. As further shown, initial geometrical parameters 303 associated with a reference shape (not shown in FIG. 3) are determined, which may include center (x,y), width, height, angle, a corner radius, all as will be explained in greater detail below. Note that the determination of a reference shape in accordance with certain embodiments, will be described in greater detail below with reference to FIG. 6A.

Note, that for simplicity of explanation and for a better understanding, the invention will be exemplified by utilizing a reference quadrilateral shape (and sometimes, more specifically, a rectangular shape) possibly with rounded corners. Note, however, that the invention is by no means bound by this example, and, accordingly, in accordance with certain embodiments, other shapes may be utilized such as a reference polygon e.g. (pentagon or hexagon) possibly with one or more rounded corners, or other shapes such as an ellipse, mutatis mutandis.

Once the initial geometrical parameters are obtained, there may follow a subsequent (iterative) numerical optimization and fitting stage 304 (which may be executed in numerical optimization and fitting modules 206 and 207, respectively—see FIG. 2). In this stage 304, the specified initial parameters are utilized and they are converted to a corresponding contour of a reference quadrilateral shape with rounded corners, and the latter may be fitted to the smoothed contour (obtained in 302) and tested against a similarity criterion. Note that the similarity criterion is generally determined internally but certain parameters thereof (e.g. in accordance with certain embodiments the convergence degree, if applicable, may be determined by the user)

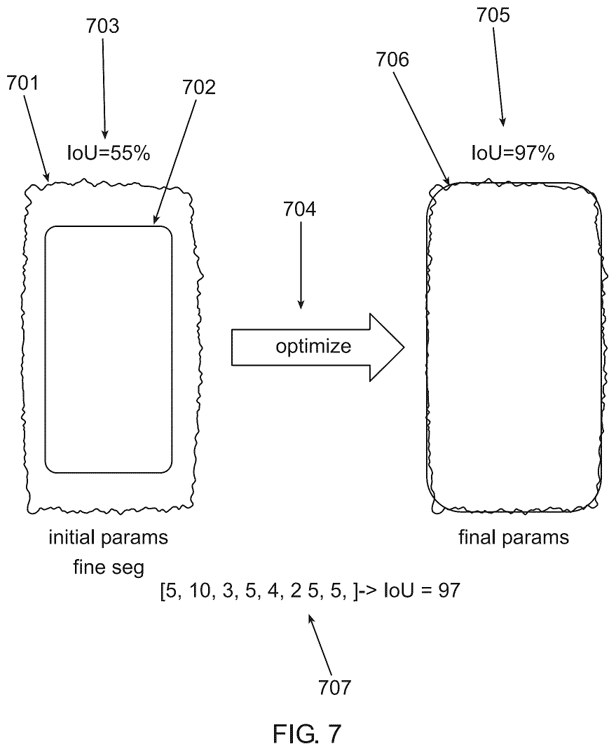

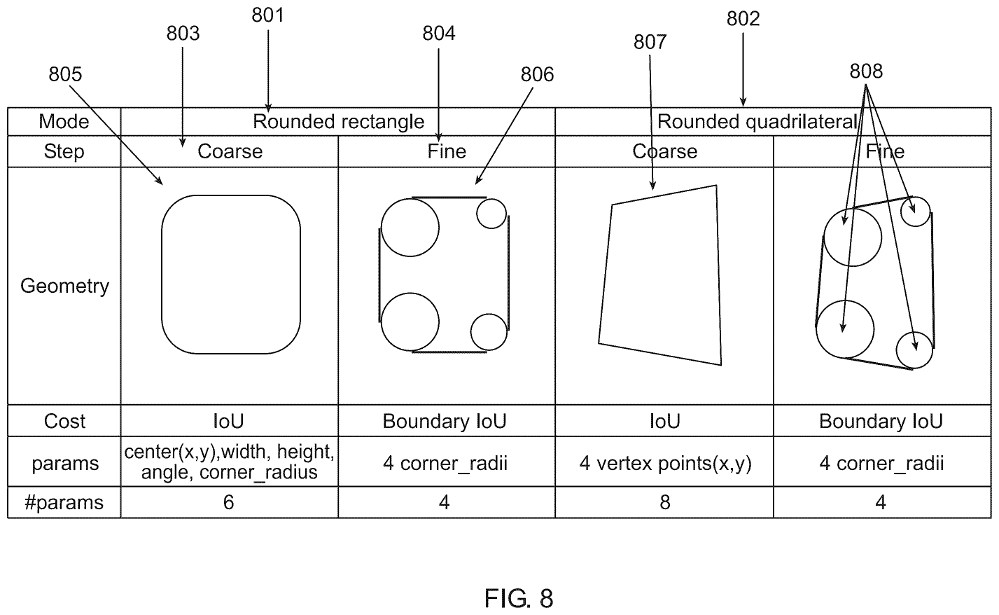

If the latter criterion is not met, the numerical optimization technique may be applied to at least one of the initial parameters (giving rise to a new set of updated geometrical parameters) and the latter parameters are then converted to an updated contour of a reference shape which is fitted to the smoothed contour and tested vis-à-vis the similarity criterion. This iterative procedure continues until the similarity criterion is met, all as will be explained in greater detail with reference to FIGS. 6A, 6B, and 7 below. As will be further explained in greater detail with reference to FIG. 8, the fitting stage may be broken down into two or more stages, and by the particular example illustrated in FIG. 3, into coarse and fine stages (304 and 305, respectively).

Once the reference quadrilateral shape is adequately fitted to the contour (namely the similarity criterion is met), the updated geometrical parameters associated with the fitted quadrilateral shape may be utilized. In accordance with certain embodiments, the updated geometrical parameters that are utilized are those that were extracted in the last iteration (when the similarity criterion was met). This however is not binding, and according to certain other embodiments the geometrical parameters extracted from earlier iterations may be used.

As explained above, accurate measurement of pattern parameters (e.g. center (x,y), width, height, angle, a corner radius) can contribute significantly to better determination of overlay misalignment (OVL) in semiconductor manufacturing processes. They may also serve for determining known per se Measurement-Based-Inspection (MBI), Distance to shape (CD) and/or possibly other parameters. Thus, generally speaking, the latter non-limiting example illustrates that utilization of one or more of the specified parameters may enable detection of defects in patterns of a semiconductor wafer.

Note that whereas the description and claims refer to feeding the output of a computational stage to the next one, the various calculation stages may include known per se interim computational stage(s) that are applied in between the so-described stages.

As discussed above, accurate measurements of OVL, CD, MBI, etc. may be useful for defect detection including process control, yield management etc., leading to more effective interventions and optimizations.

Bearing this in mind, attention is drawn to FIG. 4A illustrating, schematically, a sequence of operations for generating a contour (see e.g. stage 301 of FIG. 3), in accordance with certain embodiments of the presently disclosed subject matter. In accordance with certain embodiments, the contour is associated with an approximated quadrilateral shape with rounded corners of a representative pattern in a semiconductor wafer. Thus, with reference to FIG. 4A, an approximated quadrilateral shape (rectangle) with rounded corners 401 is representative of a pattern in a semiconductor wafer, e.g. 101 of FIG. 1A.

In accordance with certain embodiments, there may be a need to determine a finite number of points (of which, for clarity, only seven points are shown, including points 405 and 409). Note that the points are distributed across every side (see 410A, 410B) and every vertex of the approximated quadrilateral shape at a distance of, say, 1 ηm, one with respect to the other. Once the points are determined (as will be explained in further detail below) the contour may be extrapolated, e.g. by simply connecting the points. The invention is not bound by this particular manner of extrapolating the contour.

In accordance with certain embodiments, the specified points may be determined by setting an auxiliary shape, see 301′ in FIG. 3, (say, by a non-limiting example, ellipsoid 411-) that resembles the approximated quadrilateral shape 401. Then, a finite number of strips that correspond to said finite number of contour points respectively may be utilized. Thus, by this embodiment, for each desired point, a corresponding strip may be used. As shown, each of the strips traverses the contour of the quadrilateral shape, by having one end outside the shape and another end inside the shape, such that the point of traversal constitutes the corresponding contour point. For instance, strip 402 has one end at 403, and another end at 404, while traversing the contour of the shape 401 at contour point 405. The same holds true for, e.g. strip 406 which has one end at 407 and another end at 408 while traversing the contour of the shape 401 at contour point 409.

In accordance with various embodiments, the auxiliary shape 411 helps to set the orientation of the strip, for instance to be perpendicular to the gradient tangent of the auxiliary shape, as depicted in FIG. 4A.

Turning now to FIG. 4B, it illustrates schematically a one-dimensional profile that serves for determining a contour point, in accordance with certain embodiments of the presently disclosed subject matter. Thus, consider for example strip 402 and its corresponding one dimensional grey level profile (graph) 420, where the abscissa represents a location along the strip, and the ordinate represents its corresponding grey level value. As shown in FIG. 4A, a sharp increase in grey level value can be seen in the vicinity of the traversal point in the graph, and the maximum value 405 corresponds to it. Note that the invention is neither bound by utilizing the specified one-dimensional profile (e.g. ML based modeling may be used for determining the contour points), nor by selecting the maximal value in the specified one-dimensional profile.

Note that the invention is neither bound by utilizing strips, nor by the utilization of auxiliary shapes for determining the finite number of points that will serve for extrapolating the contour.

Note that, for clarity, FIG. 4A is depicted in a schematic and simplified manner only.

In accordance with certain embodiments, and as described with reference to FIG. 4A, determining only a finite number of points distributed across the contour is computationally efficient, compared, for example, to known techniques which attempt to approximate the entire contour.

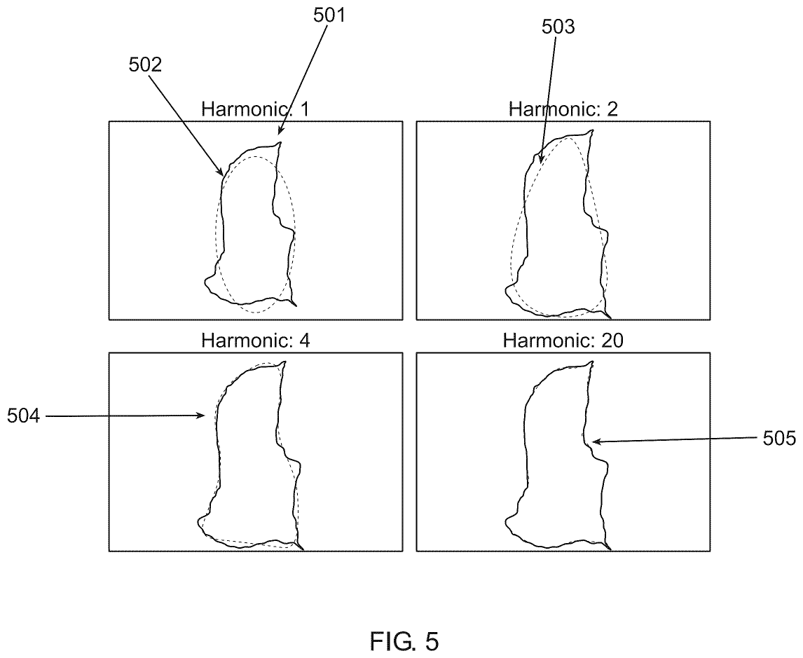

Bearing this in mind, attention is drawn to FIG. 5 illustrating, schematically, a smoothing technique (implemented e.g., in stage 302 of FIG. 3), in accordance with certain embodiments of the presently disclosed subject matter. By this particular embodiment, the contour 501 is subjected to a known per se Elliptical Fourier descriptor (EFD) smoothing technique. In accordance with certain embodiments, the smoothing degree may be adjusted, by tuning the number of Fourier series that is used. For instance, FIG. 5 illustrates four different exemplary numbers 1, 2, 4, and 20 (see reference numerals 502 to 505, respectively). Note that the greater the degree, the more close is the smoothed shape to the original contour. The degree of smoothing may be determined e.g. according to the particular application.

Note that the invention is not bound by the specific (EFD) smoothing technique, and, accordingly, other known per se techniques may be used, e.g. the Gaussian filter technique.

Moving on to FIG. 6A, it serves for illustrating schematically the next numerical optimization and fitting stage (see 304 in FIG. 3) in accordance with certain embodiments of the invention. The input to this stage may be the smoothed contour as obtained from the smoothing stage 303. The smooth contour is depicted as 601. Then, a reference quadrilateral shape (e.g. rectangle) with rounded corners 602 is selected. As already noted, the invention is not bound by using a quadrilateral shape (e.g. rectangle) with rounded corners as a reference shape, but for simplicity of explanation, the description with reference to FIG. 6 and onwards refers to a non-limiting example of a quadrilateral shape (e.g. rectangle) with rounded corners.

In accordance with certain embodiments, the reference shape 602 may be superimposed on the contour 601 in order to have an initial similarity degree. By this particular example, the reference shape contains the contour, but this is not necessarily binding (as will be exemplified e.g. with reference to FIG. 7 below). Reverting now to FIG. 6, for determining the superimposition degree of the shapes, the y_max, y_min, x_max, x_min values of the shape's contour are determined, and these values determine the vertices of the rectangle quadrilateral shape. Next, the rounded corners may be calculated such that they qualify with the equation:
X % of Min (y_max−y_min, x_max−x_min)
where X stands for, say, 15.

Based on the so obtained values, the initial parameters of the shape may be calculated or extracted (stage 303 of FIG. 3) and may include, e.g. center (x,y), width, height, four corner radii (which, as will be exemplified below, may be identical).

In accordance with certain embodiments, the smoother contour may be tilted (603). Accordingly, the so-determined reference quadrilateral shape with rounded corners 605 may also be tilted. In the latter case the initial parameters may also include rotation angle. Note that had the tilt angle (as indicated e.g. by vector 606) been ignored, the reference shape e.g. 604 would have been less optimal (in terms of superimposition degree onto the tilted smoothed contour 603) compared to the tilted reference shape e.g. 605.

Note that the invention is neither bound by the specified manner of determining initial superimposition between the respective shapes for determining the initial geometrical parameters that may be used during the numerical optimization/fitting stage, nor by the list of initial geometrical parameters.

Note that the superimposition between the contour and the reference shape may be such that the latter is partially or wholly contained in the former, or the latter is partially or wholly containing the former.

For a better understanding of the foregoing, attention is drawn to FIG. 6B, illustrating an exemplary numerical optimization and fitting sequence of operations, in accordance with certain embodiments of the presently disclosed subject matter.

Thus, Once the initial geometrical parameters are obtained (e.g. exemplary set of parameters 6001 which may be represented e.g. as an array 6002), there may follow subsequent (iterative) numerical optimization and fitting stages 304 (which may be executed in numerical optimization and fitting modules 206 and 207 respectively, see FIG. 2). By way of a non-limiting example, the numerical optimization may utilize the known per se Sequential Least Squares Programming [SLSQP] technique.

In this stage, the specified initial parameters are utilized and they are converted 6003 (in a known per se manner, to a corresponding contour of a reference quadrilateral shape with rounded corners 6004, and the latter may be fitted 6005 to the smoothed contour 6006 (obtained in 302) and tested against a similarity criterion. The fitting technique, in turn, may be e.g. the known per se Intersection Or Union (IoU) technique, or, say, Boundary IoU. Note that the invention is not bound by these particular examples.

If the latter criterion is not met (namely the shapes are not “similar enough”), the numerical optimization technique 6007 (e.g. the specified SLSQP technique) may be applied to at least one of the initial parameters (giving rise to a new set of updated geometrical parameters where one or more of the width, height, center X, center Y, corner_radius and rotation_ angle is changed (not shown in FIG. 6B). The new set of parameters are then converted 6003 to a corresponding updated contour of a reference shape which is fitted 6005 to the smoothed contour 6006 and tested vis-à-vis the similarity criterion. This iterative procedure continues until the similarity criterion is met.

Note that in accordance with certain embodiments, the iterative operation and selecting the one or more parameters to modify in each iteration, as well as the desired similarity criterion, are intrinsic to the numeral optimization technique.

Once the reference quadrilateral shape is adequately fitted to the contour (namely the similarity criterion is met), the updated geometrical parameters, preferably but not necessarily obtained from the last iteration when the similarity criterion is met, may be utilized e.g. for defect detection.

Bearing this in mind, attention is drawn to FIG. 7 illustrating the fitting sequence of operations (e.g. using the known per se Intersection over Union [IoU] fitting technique), in accordance with certain embodiments of the present invention. Having converted the initial parameters (not shown in FIG. 7) to a corresponding reference contour (702), there follows the stage of applying a fitting technique between the reference contour 702 and the smoothed contour 701 as shown schematically in FIG. 7.

The initial similarity degree between the shapes, as determined by the fitting technique, is displayed in an exaggerated manner, where the initial similarity degree is, say, 55% (703). This similarity degree does not meet the similarity criterion (as determined by the numerical optimization technique. In a next iteration of the numerical optimization technique, at least one of the parameters is modified, giving rise to a new set of updated parameters that are then converted to a corresponding updated contour of a reference shape (not shown in FIG. 7) that undergoes fitting to the smoothed contour 701 to obtain an updated similarity degree that is tested against a similarity criterion. This iterative procedure continues, in the manner specified, until the similarity degree (in the last iteration) between the contour of the updated reference shape 706 and the smoothed contour 701 meets the similarity criterion (e.g. 97% in FIG. 7). In the non-limiting example of FIG. 7, the similarity degree has been improved from 55% (703) to 97% (705). The updated parameters (e.g. updated center (x,y), width, height, four corner radii as depicted schematically in array 707) which correspond to the contour of the updated reference shape 706 (associated with the last numerical optimization iteration) may then be used.

As was explained above, accurate determination of the specified parameters (provided for illustrative purposes only) may lead to accurate measurements of OVL, CD, MBI, etc. which may improve the process of defect detection including e.g. process control, yield management etc., in semiconductor manufacturing.

Note that the invention is not bound by the IoU technique for fitting the shapes, and, accordingly, other known per se techniques may be used, e.g. the Boundary IoU.

As specified, the invention is neither bound by the specified list of parameters, nor by the number of computational stages that are required for implementing the fitting stage. Thus, by way of example, and as shown in FIG. 3, the fitting stage may be broken down into two stages, defined as coarse (305) and fine (306). The invention is obviously not bound by the utilization of two stages according to the specific example discussed below. Note that in accordance with certain embodiments, utilization of more than one numerical optimization and fitting computational stage, e.g. coarse in fine sub-stages as discussed herein, may be regarded as “more efficient” in terms of computational complexity and/or requiring less computer storage space.

For a better understanding of the ongoing, attention is drawn to FIG. 8, illustrating two non-limiting examples of utilizing two computational stages (coarse and fine respectively), for achieving the numerical optimization and fitting sequence of operation. FIG. 8 illustrates two examples: the first (801) named rounded rectangle, and the other (802) named rounded quadrilateral.

Turning at first to the rounded rectangle example, it illustrates the relevant information that pertains to the coarse stage (803) and the fine stage (804). By this example, the selected geometry (a reference quadrilateral shape with rounded corners 805) is composed of a rectangle with rounded corners having a common radius. There are six selected initial parameters, namely: center (x,y), width, height, angle, and corner radius. The fitting technique is IoU. After having applied the numerical optimization and fitting technique as explained e.g. with reference to FIGS. 6B and 7 above, the updated parameters associated with the fitted reference quadrilateral shape with rounded corners are determined, and the numerical optimization and fitting sequence proceeds to the next fine stage.

In this stage, the fitted reference quadrilateral shape with rounded corners is still a rectangle with rounded corners 806 (wherein the initial parameters are those that were outputted from the coarse computational stage), however, unlike geometry 805, geometry 806 may have four distinct corner radii, namely the fine stage aims at determining four parameters (four possibly distinct corner radii), and may utilize the known Boundary IoU fitting technique.

Turning now to the rounded quadrilateral example (802), it illustrates a reference rounded quadrilateral geometry (807) and the numerical optimization, and the fitting technique aims at calculating updated parameters that include four vertex points, each having (x,y) coordinates (giving rise to 8 initial parameters) associated with the fitted reference rounded quadrilateral geometry, and, to this end, the IoU fitting technique may be used. In the subsequent fine calculation stage, updated parameters that include four possibly distinct corner radii (808) associated with the fitted reference rounded quadrilateral geometry, are calculated using e.g. the Boundary IoU fitting technique.

Note that in each distinct fitting stage (say coarse and/or fine), the same numerical optimization technique may be used (e.g. the specified SLSQP technique), or in accordance with certain embodiments, in two or more fitting stages, a different numerical optimization technique may be utilized.

As specified, the numerical optimization and/or fitting stage may be broken down into more than two stages, e.g. up to n stages wherein n is the number of updated geometrical parameters, e.g. according to the rounded rectangle example 801 up to ten numerical optimization/fitting stages (corresponding to 6+4 updated parameters), or according to the rounded quadrilateral example 802 up to twelve numerical optimization/fitting stages (corresponding to 8+4 updated parameters).

There are known in the art techniques for fitting shapes (e.g. ellipse), but the known techniques do not utilize a combination of numerical optimization and fitting techniques in the manner specified, and as such tend to be not accurate enough. For instance, reverting to FIG. 1C, as shown, the smoothed contour is designated as 1010 (marked in solid line) and the fitted reference is an ellipse shape 1020 (marked in dashed line). As shown, the similarity degree is degraded as the contour of the ellipse shape extends upwardly and/or downwardly compared to the smoother contour. In contrast, turning to the other chart of FIG. 1C, the fitted reference contour of quadrilateral shape with rounded corners 1015 marked in dashed line (as achieved using the technique including applying numerical optimization and fitting according to certain embodiments of the invention), has a very high similarity degree to the smoothed contour shape 1010, and as such the resulting corresponding updated parameters enable hi-quality detection of defects in patterns of a semiconductor wafer.

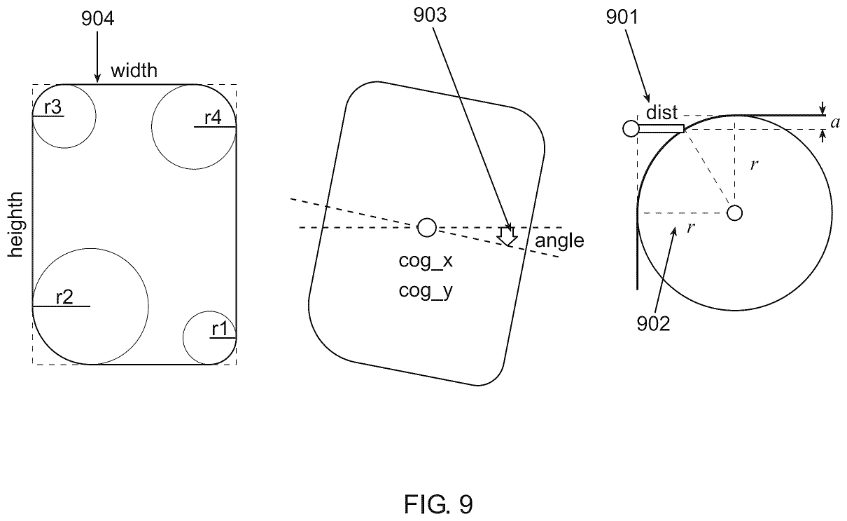

Attention is now drawn to FIG. 9, illustrating, schematically, a sequence of operations for determining updated geometrical parameters of the fitted shape, in accordance with certain embodiments of the presently disclosed subject matter. Thus, for example, the desired parameter is dist (standing for “distance”) 901. Based on the so-extracted radius 902 (in the manner discussed above), and additional provided parameter value a (903), the desired parameter “distance” may be calculated using known per se geometrical calculation.

By yet another example, the reference shape may be tilted by a rotation angle (903) relative to the basic geometry (904). In the latter case, the initial parameters may include rotation angle, and, after applying the fitting technique, an updated (and more accurate) rotation angle may be extracted. Note that the invention is not bound by the specific examples of the calculated and/or extracted parameters which may vary according to the particular application, and, in certain cases may be directly extracted, and in other cases an additional calculation stage may be required. Note, incidentally, that throughout the description the terms “shape and “geometry” may be used interchangeably.

It is to be noted that examples, equations, and numeral values illustrated in the present disclosure are illustrated merely for exemplary purposes and should not be regarded as limiting the present disclosure in any way. Other appropriate examples/implementations can be used in addition to, or in lieu of the above.

In the detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the discussions, it is appreciated that, throughout the specification, discussions, utilizing terms such as obtain, fit, determine, or the like, refer to the action(s) and/or process(es) of a computer that manipulate and/or transform data into other data, said data represented as physical, such as electronic, quantities and/or said data representing the physical objects. The term “computer” should be expansively construed to cover any kind of hardware-based electronic device with data processing capabilities as described, e.g., with reference to FIG. 2.

The processor referred to in the current disclosure can represent one or more general-purpose processing devices, such as a microprocessor, a central processing unit, or the like. More particularly, the processor may be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processor may also be one or more special-purpose processing devices, such as an application specific integrated circuit (ASIC), a field programmable gate array (FPGA), a digital signal processor (DSP), a network processor, or the like. The processor is configured to execute instructions for performing the operations and steps discussed herein.

The memory referred to herein can comprise a main memory (e.g., read-only memory (ROM), flash memory, dynamic random-access memory (DRAM) such as synchronous DRAM (SDRAM) or Rambus DRAM (RDRAM), etc.), and a static memory (e.g., flash memory, static random-access memory (SRAM), etc.).

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “examination” used in this specification should be expansively construed to cover any kind of operations related to defect detection, defect review and/or defect classification of various types, segmentation, and/or other operations during and/or after the wafer's fabrication process. Examination is provided by using non-destructive examination tools during or after manufacture of the wafer to be examined. By way of non-limiting example, the examination process can include runtime scanning (in a single or in multiple scans), imaging, sampling, detecting, reviewing, measuring (including, e.g., measurements of characteristics of wafer holes and hole's bottom), classifying and/or other operations provided with regard to the wafer or parts thereof, using the same or different inspection tools. Likewise, examination can be provided prior to manufacture of the wafer to be examined, and can include, for example, generating an examination recipe(s) and/or other setup operations. It is noted that, unless specifically stated otherwise, the term “examination”, or its derivatives used in this specification, are not limited with respect to resolution or size of an inspection area. A variety of non-destructive examination tools includes, by way of non-limiting example, scanning electron microscopes (SEM), atomic force microscopes (AFM), optical inspection tools, etc.

The term “examination tool(s)” used herein should be expansively construed to cover any tools that can be used in examination-related processes, including, by way of non-limiting example, scanning (in a single or in multiple scans), imaging, sampling, reviewing, measuring, classifying, and/or other processes provided with regard to the wafer or parts thereof.

It is to be noted that, the term “image(s)” used herein can refer to original images of the wafer captured by the examination tool during the manufacturing process, derivatives of the captured images obtained by various pre-processing stages, and/or computer-generated design data-based images. It is to be noted that in some cases the images referred to herein can include image data (e.g., captured images, processed images, etc.) and associated numeric data (e.g., metadata, hand-crafted attributes, etc.). It is further noted that image data can include data related to one or more layers of interest of the wafer.

The terms “similar” or “sufficiently similar”, “distance”, used in this specification should be expansively construed to cover, in accordance with certain embodiments, any kind of well-known techniques such as measuring distances (e.g. L1 Norm, L2 Norm).

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the following detailed description, numerous specific details are set forth in order to provide a thorough understanding of the methods and apparatus.

Note that in accordance with certain embodiments, the order of computational stages described herein with reference to the drawings is not necessarily binding. For instance, the order of steps may be changed, steps may be modified or deleted, and/or other steps may be added instead of or in addition to those disclosed herein.

It is to be understood that the present disclosure is not limited in its application to the details set forth in the description contained herein or illustrated in the drawings.

It will also be understood that the system, according to the present disclosure, may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A system for rounded quadrilateral shape fitting comprising a processing and memory circuitry (PMC) configured to:
obtain a contour associated with an approximated quadrilateral shape with rounded corners of a representative pattern in a semiconductor wafer and smoothing the contour;
obtain geometrical parameters associated with a contour of a reference shape;
perform iteratively until a similarity criterion is met:
a) convert the updated geometrical parameters generated in the current iteration to a corresponding contour of a reference shape;
(b) fit the corresponding contour of the reference shape to the smoothed contour;
(c) test whether the fitted contour of the reference shape and the smoothed contour meet a similarity criterion, and if said similarity criterion is not met, apply a numerical optimization to at least one of said updated geometrical parameters from the current iteration to generate a new set of updated geometrical parameters for use in a subsequent iteration,
thereby, if said similarity criterion is met, enabling detection of defects in patterns of a semiconductor wafer utilizing at least updated geometrical parameters generated in one of said iterations, wherein the patterns resemble a quadrilateral shape with rounded corners.

2. The system according to claim 1, wherein said reference shape is a quadrilateral shape with rounded corners.

3. The system according to claim 1, wherein said PMC is configured to fit the reference shape to the smoothed contour in at least two fitting stages, wherein, in each stage, a distinct number of said initial parameters are updated to thereby improve computational complexity compared to the computational complexity, had all the initial parameters been updated in a single fitting stage.

4. The system according to claim 1, wherein said PMC is configured to utilize different fitting techniques for at least two of said stages.

5. The system according to claim 2, wherein said PMC is configured to fit the reference quadrilateral shape with rounded corners to the smoothed contour in two fitting stages, wherein, in the first stage, the fitting includes an IoU fitting technique, and the center (x,y), width, height, angle, corner radius updated parameters of the fitted quadrilateral shape are determined, and in the second stage the fitting includes a Boundary IoU technique, and the four corner radii updated parameters of the fitted quadrilateral shape are determined.

6. The system according to claim 2, wherein said PMC is configured to fit the reference quadrilateral shape with rounded corners to the smoothed contour in two fitting stages, wherein, in the first stage, the fitting includes an IoU fitting technique, and the four vertex points (x,y) updated parameters of the fitted shape with rounded corners are determined, and in the second stage the fitting includes a Boundary IoU technique, and the four corner radii updated parameters of the fitted quadrilateral shape are determined.

7. The system according to claim 1, wherein said PMC is configured to fit the reference shape with rounded corners to the smoothed contour in n fitting stages, wherein n is the number of updated geometrical parameters.

8. The system according to claim 1 wherein said PMC is configured to obtain the contour associated with an approximated quadrilateral shape with rounded corners of a representative pattern in a semiconductor wafer, including:
determine a finite number of contour points that are distributed across every side and every vertex of said approximated quadrilateral shape;
extrapolate the contour of the model based on said determined plurality of contour points.

9. The system according to claim 8, wherein said PMC is configured to determine said finite number of contour points, including:
utilize an auxiliary shape that substantially overlaps said approximated quadrilateral shape with rounded corners;
determine a finite number of strips that correspond to said finite number of contour points, respectively, wherein each of the strips traverses the contour of the quadrilateral shape, by starting outside the shape and ending inside the shape, such that the point of traversal constitutes the corresponding contour point.

10. The system according to claim 1, wherein said auxiliary shape is fed as an input.

11. The system according to claim 1, wherein said (PMC) is configured to smooth said contour utilizing an Elliptical Fourier Descriptor (EFD) technique.

12. The system according to claim 1, wherein said initial parameters include center (x,y), width, height, angle, and a corner radius.

13. A method for rounded quadrilateral shape fitting, comprising, by a processing and memory circuitry (PMC):
obtaining a contour associated with an approximated quadrilateral shape with rounded corners of a representative pattern in a semiconductor wafer and smoothing the contour;
obtaining geometrical parameters associated with a contour of a reference shape [not necessarily with rounded corners]
performing iteratively until a similarity criterion is met:
a) converting the updated geometrical parameters generated in the current iteration to a corresponding contour of a reference shape;
(b) fit the corresponding contour of the reference shape to the smoothed contour;
(c) test whether the fitted contour of the reference shape and the smoothed contour meet a similarity criterion, and if said similarity criterion is not met, apply a numerical optimization to at least one of said updated geometrical parameters from the current iteration to generate a new set of updated geometrical parameters for use in a subsequent iteration,
thereby, if said similarity criterion is met, enabling detection of defects in patterns of a semiconductor wafer utilizing at least updated geometrical parameters generated in one of said iterations, wherein the patterns resemble a quadrilateral shape with rounded corners.

14. The method according to claim 13, wherein said reference shape is a quadrilateral shape with rounded corners.

15. The method according to claim 13, wherein said fitting of the reference shape to the smoothed contour includes at least two fitting stages wherein, in each stage, a distinct number of said initial parameters are updated to thereby improve computational complexity compared to the computational complexity, had all the initial parameters been updated in a single fitting stage.

16. The method according to claim 13, further comprising utilizing different fitting techniques for at least two of said stages.

17. The method according to claim 14, wherein said fitting of the reference quadrilateral shape with rounded corners to the smoothed contour includes two fitting stages, wherein, in the first stage, the fitting includes an IoU fitting technique, and the center (x,y), width, height, angle, corner radius updated parameters of the fitted quadrilateral shape are determined, and in the second stage the fitting includes a Boundary IoU technique, and the four corner radii updated parameters of the fitted quadrilateral shape are determined.

18. The method according to claim 14, wherein fitting the reference quadrilateral shape with rounded corners to the smoothed contour includes two fitting stages, wherein, in the first stage, the fitting includes an IoU fitting technique, and the four vertex points (x,y) updated parameters of the fitted quadrilateral shape are determined, and in the second stage the fitting includes the Boundary IoU technique, and the four corner radii updated parameters of the fitted quadrilateral shape are determined.

19. A non-transitory computer readable storage medium tangibly embodying a program of instructions that, when executed by a computer, cause the computer to perform a method for rounded quadrilateral shape fitting, comprising, by a processing and memory circuitry (PMC):
obtaining a contour associated with an approximated quadrilateral shape with rounded corners of a representative pattern in a semiconductor wafer and smoothing the contour;
obtaining geometrical parameters associated with a contour of a reference shape;
performing iteratively until a similarity criterion is met:
a) converting the updated geometrical parameters generated in the current iteration to a corresponding contour of a reference shape;
(b) fit the corresponding contour of the reference shape to the smoothed contour;
(c) test whether the fitted contour of the reference shape and the smoothed contour meet a similarity criterion, and if said similarity criterion is not met, apply a numerical optimization to at least one of said updated geometrical parameters from the current iteration to generate a new set of updated geometrical parameters for use in a subsequent iteration,
thereby, if said similarity criterion is met, enabling detection of defects in patterns of a semiconductor wafer utilizing at least updated geometrical parameters generated in one of said iterations, wherein the patterns resemble a quadrilateral shape with rounded corners.

20. The non-transitory computer readable storage medium according to claim 19, wherein said reference shape is a quadrilateral shape with rounded corners.
